(19) United States
(12) Patent Application Publication
(10) Pub. No.: US 2023/0081585 A1
(43) Pub. Date: Mar. 16, 2023

(54) SYSTEMS AND METHODS FOR USING PHASE CHANGE MATERIAL TO AID COOLING OF INFORMATION HANDLING RESOURCES

(71) Applicant: Dell Products L.P., Round Rock, TX (US)

(72) Inventors: Yuan Chen, Shanghai (CN); Xiaoling Zhou, Nantong City (CN); Chengyi Gu, Dalian (CN); Mingming Zhang, Shanghai City (CN)

(73) Assignee: Dell Products L.P., Round Rock, TX (US)

(21) Appl. No.: 17/496,087

(22) Filed: Oct. 7, 2021

(30) Foreign Application Priority Data
Sep. 16, 2021 (CN) 202111090061.8

(51) Int. Cl. H05K 7/20

(52) U.S. Cl. CPC H05K 7/20445; H05K 7/2029

(57) ABSTRACT

An information handling system may include an information handling resource and a phase change material assembly thermally coupled to the information handling resource and comprising a fixture formed from thermally-conductive material and having an enclosed plenum and phase change material enclosed within the enclosed plenum and having a phase change temperature at which the phase change material changes from a first physical phase to a second physical phase, such that during a phase change of the phase change material, the phase change material absorbs thermal energy from the information handling resource to maintain the information handling resource at approximately the phase change temperature.

### TECHNICAL FIELD

The present disclosure relates in general to information handling systems, and more particularly to methods and systems for using phase change material to aid in cooling of information handling resources.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems are increasingly using persistent memory technologies such as Non-Volatile Dual In-line Memory Modules (NVDIMMs). An NVDIMM is a memory module that may retain data even when electrical power is removed whether from an unexpected power loss, system crash, or from a normal system shutdown. To enable such functionality, an NVDIMM may include a traditional dynamic random access memory (DRAM) which may store data during normal operation when electrical power is available from one or more power supply units and a flash memory to back up data present in the DRAM when a loss of electrical power from the power supply units occurs. A battery, capacitor, or other energy storage device either internal or external to the NVDIMM may supply electrical energy for a “save” or “vaulting” operation to transfer data from the DRAM to the flash memory in response to a power loss event from the power supply units. The transfer of data from DRAM to flash memory is not typically visible to an operating system executing on an information handling system, instead being performed as a background operation on the NVDIMM itself.

However, during a vaulting operation, because of the limited energy that may be provided from the energy storage device to perform the vault operation, an air mover (e.g., fan or blower) that may typically be present in an information handling system to cool components of the information handling resource may power down or power off, to leave sufficient electrical energy for completing the vaulting operation. However, during the vaulting operation, the energy storage device and the flash memory may begin to heat, and the lack of air mover cooling may cause such devices to overheat, which may potentially lead to data loss.

### SUMMARY

In accordance with the teachings of the present disclosure, the disadvantages and problems associated with existing approaches to performing a memory vaulting operation may be reduced or eliminated.

In accordance with embodiments of the present disclosure, an information handling system may include an information handling resource and a phase change material assembly thermally coupled to the information handling resource and comprising a fixture formed from thermally-conductive material and having an enclosed plenum and phase change material enclosed within the enclosed plenum and having a phase change temperature at which the phase change material changes from a first physical phase to a second physical phase, such that during a phase change of the phase change material, the phase change material absorbs thermal energy from the information handling resource to maintain the information handling resource at approximately the phase change temperature.

In accordance with these and other embodiments of the present disclosure, a phase change material assembly configured to be thermally coupled to a heat-generating device and may include a fixture formed from thermally-conductive material and having an enclosed plenum and phase change material enclosed within the enclosed plenum and having a phase change temperature at which the phase change material changes from a first physical phase to a second physical phase, such that during a phase change of the phase change material, the phase change material absorbs thermal energy from the heat-generating device to maintain the heat-generating device at approximately the phase change temperature.

In accordance with these and other embodiments of the present disclosure, a method may include thermally coupling a phase change material assembly to a heat-generating device, wherein the phase change material assembly comprises a fixture formed from thermally-conductive material and having an enclosed plenum and phase change material enclosed within the enclosed plenum and having a phase change temperature at which the phase change material changes from a first physical phase to a second physical phase, such that during a phase change of the phase change material, the phase change material absorbs thermal energy from the heat-generating device to maintain the heat-generating device at approximately the phase change temperature.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure; and

FIG. 2 illustrates a side elevation view of selected portions of the information handling system depicted in FIG. 1, in accordance with embodiments of the present disclosure.

### DETAILED DESCRIPTION

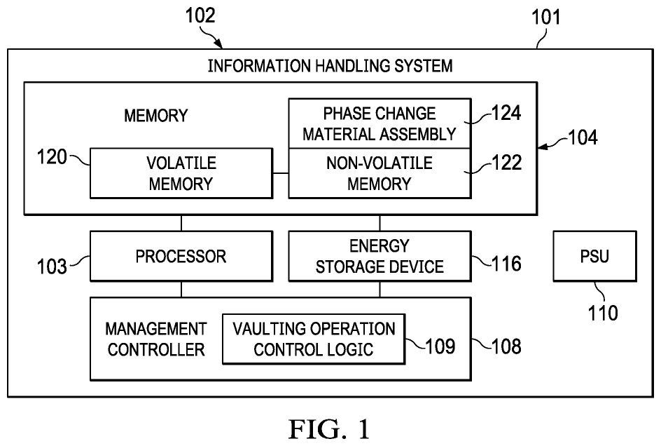

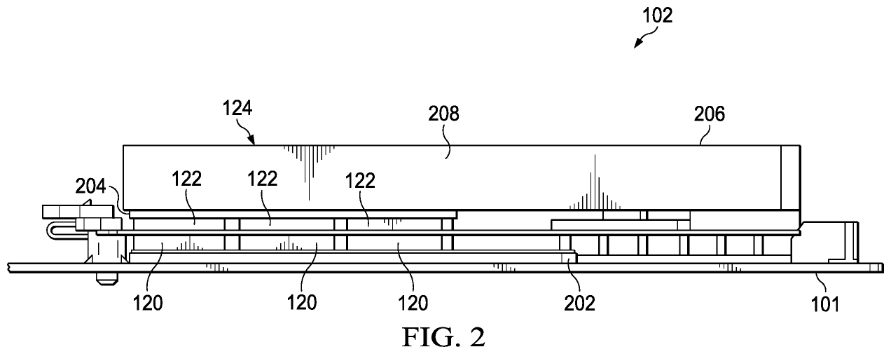

Preferred embodiments and their advantages are best understood by reference to FIGS. 1 and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a block diagram of an example information handling system 102, in accordance with embodiments of the present disclosure. As shown in FIG. 1, information handling system 102 may include chassis 101, a processor 103, a memory 104 communicatively coupled to processor 103, a management controller 108 communicatively coupled to processor 103, a power supply unit (PSU) 110, and an energy storage device 116.

Chassis 101 may include any suitable enclosure for housing the various components of information handling system 102, and may also be referred to as a rack, tower, enclosure, and/or housing.

Processor 103 may include any system, device, or apparatus configured to interpret and/or execute program instructions and/or process data, and may include, without limitation, a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to an associated processor 103 and may include any system, device, or apparatus configured to retain program instructions and/or data for a period of time (e.g., computer-readable media). A memory 104 may include RAM, EEPROM, a PCMCIA card, flash memory, magnetic storage, opto-magnetic storage, or any suitable selection and/or array of volatile or non-volatile memory that retains data after power to information handling system 102 is turned off. As shown in FIG. 1, memory 104 may comprise a persistent memory (e.g., comprising one or more NVDIMMs) that includes a volatile memory 120 (e.g., DRAM or other volatile random-access memory) and non-volatile memory 122 (e.g., flash memory or other non-volatile memory). During normal operation, when PSU 110 provides adequate power to components of information handling system 102, data written to memory 104 from processor 103 may be stored in volatile memory 120. However, in the event of loss of system input power or a power fault of PSU 110 that prevents delivery of adequate electrical energy from PSU 110 to memory 104, data stored in volatile memory 120 may be transferred to non-volatile memory 122 in a vaulting operation. After input power is restored, or a faulty PSU 110 is replaced, such that PSU 110 is again operable to provide sufficient electrical energy to information handling resources of an information handling system 102, on the subsequent power-on of information handling system 102, data may be copied from the non-volatile memory 122 back to volatile memory 120 via a restore operation. The combined actions of data vaulting and then data restore may allow the data to remain persistent through a power disruption. Although not explicitly shown in FIG. 1, memory 104 may also include hardware, firmware, and/or software for carrying out vaulting operations.

As also shown in FIG. 1, a phase change material assembly 124 may be thermally coupled to non-volatile memory 122. As described in greater detail below, phase change material assembly 124 may include phase change material. During a vaulting operation, when airflow-based cooling may be unavailable, such phase change material may go through a change in physical phase (e.g., from solid to liquid), such phase change absorbing heat generated by non-volatile memory 122 while maintaining a significantly constant temperature (e.g., the melting point of the phase change material) during such phase change, thus maintaining non-volatile memory 122 at or near such temperature, and preventing overheating of non-volatile memory 122. After completion of the vaulting operation, the phase change material may again change state (e.g., from liquid to solid), dissipating the heat transferred to it from non-volatile memory 122. Thus, advantageously, the phase change material may allow for energy-efficient thermal control of non-volatile memory 122, as little or no power consumption may be required for thermal control of non-volatile memory 122 using the phase change material.

For purposes of clarity and exposition, phase change material assembly 124 is only shown in FIG. 1 to be in thermal contact with non-volatile memory 122. However, in some embodiments, phase change material assembly 124 (or other similar phase change material assemblies) may be thermally coupled to other components of information handling system 102, including without limitation energy storage device 116, and thus may also provide for cooling/thermal maintenance of such other components during a vaulting operation.

Management controller 108 may be configured to provide out-of-band management facilities for management of information handling system 102. Such management may be made by management controller 108 even if information handling system 102 is powered off or powered to a standby state. In certain embodiments, management controller 108 may include or may be an integral part of a remote access controller (e.g., a Dell Remote Access Controller or Integrated Dell Remote Access Controller). In other embodiments, management controller 108 may include a chassis management controller, a baseboard management controller, or an enclosure controller.

As shown in FIG. 1, management controller 108 may include vaulting operation control logic 109. Vaulting operation control logic 109 may comprise any system, device, or apparatus configured to monitor a health status of PSU 110 and selectively enable or disable the execution of vaulting operations on information handling system 102. Although FIG. 1 depicts vaulting operation control logic 109 as integral to management controller 108, in some embodiments, vaulting operation control logic 109 may be external to management controller 108 and may be embodied in a complex programmable logic device or other suitable piece of electronic hardware.

Generally speaking, a PSU 110 may include any system, device, or apparatus configured to supply electrical current to one or more information handling resources of information handling system 102. For example, a PSU 110 may provide electrical energy via a main power rail and an auxiliary power rail. The main power rail may generally be used to provide power to information handling resources of information handling system 102 when information handling system 102 is turned on. On the other hand, the auxiliary power rail may generally be used to provide power to certain auxiliary information handling resources when energy is not supplied via the main power rail. For example, the auxiliary power rail may be used to provide power to management controller 108 when electrical energy is not provided to processor 103, memory 104, and/or other information handling resources via the main power rail.

An energy storage device 116 may comprise any system, device, or apparatus configured to store energy which may be used by memory 104 to perform vaulting operations in response to a loss of an input source of energy (e.g., loss of alternating current or direct current source) or other power fault of one or more PSUs 110. In some embodiments, energy storage device 116 may comprise a battery configured to convert stored chemical energy into electrical energy. In other embodiments, energy storage device 116 may comprise a capacitor or “supercap” configured to store electrical energy and deliver such electrical energy to memory 104 when needed to perform vaulting operations (e.g., by closure of a switch to electrically couple such capacitor to components of memory 104). Although energy storage device 116 is shown in FIG. 1 as external to memory 104, in some embodiments energy storage device 116 may be integral to memory 104. In these and other embodiments, energy storage device 116 may be charged from one or more PSUs 110. In some embodiments, an energy storage device 116 may be communicatively coupled to an associated management controller 108 via a systems management interface such as, for example, Inter-Integrated Circuit (i2C), System Management Bus (SMBus) or Power Management Bus (PMBus), allowing management controller 108 to receive health and status (e.g., state of charge) from and/or communicate commands to energy storage device 116. In some embodiments, energy storage device 116 may provide energy to a plurality of persistent memory 104 devices.

In addition to processor 103, memory 104, management controller 108, PSU 110, and energy storage device 116, information handling system 102 may include one or more other information handling resources. For example, in some embodiments, information handling system 102 may include more than one energy storage device 116, more than one PSU 110, and/or more than one memory 104.

FIG. 2 illustrates a side elevation view of selected portions of information handling system 102 depicted in FIG. 1. As shown in FIG. 2, memory 104 may be embodied with a printed circuit board 202 enclosed within chassis 101, such printed circuit board 202 having modules for volatile memory 120 and non-volatile memory 122 mounted thereon.

As also shown in FIG. 2, phase change material assembly 124 may include a fixture 206 mechanically mounted within chassis 101 such that fixture 206 is in thermal communication with non-volatile memory 122 via thermal interface material 204. Fixture 206 may be constructed from a metal or other thermally-conductive material. As further shown in FIG. 2, fixture 206 may include an enclosed plenum or cavity comprising phase change material 208. Accordingly, heat generated by non-volatile memory 122 may be transferred to phase change material 208 via thermal interface material 204 and fixture 206.

Phase change material 208 may comprise any substance configured to, under the application of heat at or above a melting temperature of such substance, change physical phase from solid to liquid. In some embodiments, phase change material 208 may be selected to have a melting point at or below a maximum desired operating temperature for non-volatile memory 122 or other heat-generating component of information handling system. For example, in some embodiments, phase change material 208 may comprise RUBITHERM® RT64HC with a melting temperature of approximately 64° C.

In operation, phase change material 208 may absorb thermal energy during the process of phase change, and the temperature of phase change material 208 (as is the case with all other materials) may not increase above its melting point until it has fully transitioned from solid to liquid. Thus, during a vaulting process, a temperature of non-volatile memory 122 may increase until reaching the melting point of phase change material 208 at which phase change material 208 may begin melting and absorb heat generated by non-volatile memory 122. During the melting process, the phase change material 208 may maintain a constant temperature at the melting point, thus maintaining the temperature of phase change material 208 at or near the melting point. At the end of the vaulting process, phase change material 208 may release thermal energy to its surroundings and recover to its solid state.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
an information handling resource; and
a phase change material assembly thermally coupled to the information handling resource and comprising:
a fixture formed from thermally-conductive material and having an enclosed plenum;
phase change material enclosed within the enclosed plenum and having a phase change temperature at which the phase change material changes from a first physical phase to a second physical phase, such that during a phase change of the phase change material, the phase change material absorbs thermal energy from the information handling resource to maintain the information handling resource at approximately the phase change temperature.

2. The information handling system of claim 1, wherein:
the phase change temperature is a melting point of the phase change material;
the first physical phase is solid; and
the second physical phase is liquid.

3. The information handling system of claim 1, wherein the information handling resource comprises a non-volatile memory.

4. The information handling system of claim 1, wherein the information handling resource comprises an energy storage device for storing electrical energy.

5. A phase change material assembly configured to be thermally coupled to a heat-generating device and comprising:
a fixture formed from thermally-conductive material and having an enclosed plenum;
phase change material enclosed within the enclosed plenum and having a phase change temperature at which the phase change material changes from a first physical phase to a second physical phase, such that during a phase change of the phase change material, the phase change material absorbs thermal energy from the heat-generating device to maintain the heat-generating device at approximately the phase change temperature.

6. The phase change material assembly of claim 5, wherein:
the phase change temperature is a melting point of the phase change material;
the first physical phase is solid; and
the second physical phase is liquid.

7. The phase change material assembly of claim 5, wherein the heat-generating device comprises a non-volatile memory.

8. The phase change material assembly of claim 5, wherein the heat-generating device comprises an energy storage device for storing electrical energy.

9. A method comprising:
thermally coupling a phase change material assembly to a heat-generating device, wherein the phase change material assembly comprises:
a fixture formed from thermally-conductive material and having an enclosed plenum; and
phase change material enclosed within the enclosed plenum and having a phase change temperature at which the phase change material changes from a first physical phase to a second physical phase, such that during a phase change of the phase change material, the phase change material absorbs thermal energy from the heat-generating device to maintain the heat-generating device at approximately the phase change temperature.

10. The method of claim 9, wherein:
the phase change temperature is a melting point of the phase change material;
the first physical phase is solid; and
the second physical phase is liquid.

11. The method of claim 9, wherein the heat-generating device comprises a non-volatile memory.

12. The method of claim 9, wherein the heat-generating device comprises an energy storage device for storing electrical energy.
